(19) United States
(12) Patent Application Publication
(10) Pub. No.: US 2015/0231987 A1
(43) Pub. Date: Aug. 20, 2015

(54) Adjustment Module and Battery Management System Thereof

(71) Applicant: Energy Pass Incorporation, Hsinchu City (TW)

(72) Inventor: Ming-Wei Lin, Hsinchu City (TW)

(73) Assignee: Energy Pass Incorporation, Hsinchu City (TW)

(21) Appl. No.: 14/183,466

(22) Filed: Feb. 18, 2014

(51) Int. Cl. B60L 11/18; H03M 1/12; H03M 1/18; H03M 1/00

(52) U.S. Cl. CPC B60L 11/1866; H03M 1/002; H03M 1/1245; H03M 1/186

(57) ABSTRACT

An adjustment module for an analog to digital converter (ADC) of a battery management system (BMS) includes a detection unit, for detecting a slop of an input current, to generate a sampling control signal; and a sampling frequency adjustment unit, for adjusting a sampling frequency of the ADC according to the sampling control signal.

### BACKGROUND OF THE INVENTION

1. Field of the Invention

The present invention relates to an adjustment module and battery management system (BMS) thereof, and more particularly, to an adjustment module and BMS thereof capable of dynamically adjusting a sampling frequency and an input power of an analog to digital converter (ADC), so as to reduce power consumption and design complexity.

2. Description of the Prior Art

Conventionally, a motor includes magnets and coils and thus a back electro motive force is generated when the motor rotates in a stable state. Therefore, a voltage applied on the motor only renders a small current due to the back electro motive force.

However, when the motor just starts rotating or suddenly accelerates, a corresponding back electro motive force is not yet generated, and thus a large current occurs. In such a situation, since an analog to digital converter (ADC) of a battery management system (BMS) is utilized for measuring a current of a battery set utilized for providing power for the motor, the ADC may be saturated since the large current is beyond a dynamic range of the ADC, or the ADC may not accurately record the sudden large current of the battery set due to a low sampling frequency as shown in FIG. 1, wherein dotted lines indicate sampling timings and a peak of the current is not sampled.

In the prior art, the conventional ADC is over-designed to have a wide dynamic range and a high large sampling frequency, to avoid saturation and inaccuracy due to the sudden large current, causing more power consumption and design complexity. Thus, there is a need to improve over the prior art.

### SUMMARY OF THE INVENTION

It is therefore an objective of the present invention to provide an adjustment module and battery management system (BMS) thereof capable of dynamically adjusting a sampling frequency and an input power of an analog to digital converter (ADC), so as to reduce power consumption and complexity.

The present invention discloses an adjustment module for an analog to digital converter (ADC) of a battery management system (BMS). The adjustment module includes a detection unit, for detecting a slop of an input current, to generate a sampling control signal; and a sampling frequency adjustment unit, for adjusting a sampling frequency of the ADC according to the sampling control signal.

The present invention further discloses a battery management system (BMS). The BMS includes an ADC, for generating an ADC output signal according to a sampling frequency; and an adjustment module. The adjustment module includes a detection unit, for detecting a slop of an input current, to generate a sampling control signal; and a sampling frequency adjustment unit, for adjusting the sampling frequency of the ADC according to the sampling control signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional battery management system shown sampling an input current.

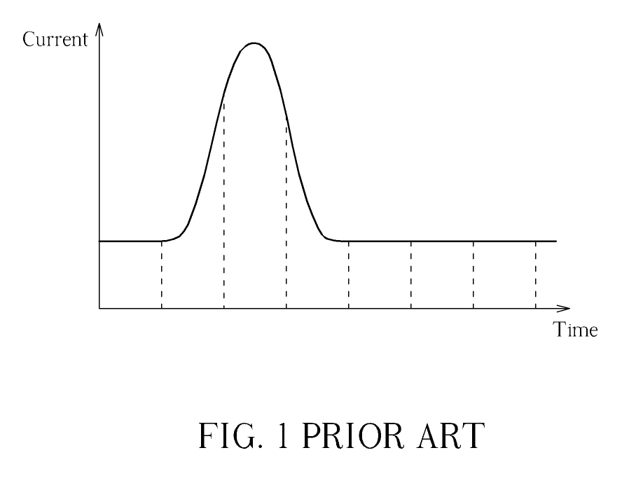

FIG. 2 is a schematic diagram of a battery management system according to an embodiment of the present invention.

FIG. 3 is a schematic diagram of the battery management system shown in FIG. 2 sampling an input current according to an embodiment of the present invention.

### DETAILED DESCRIPTION

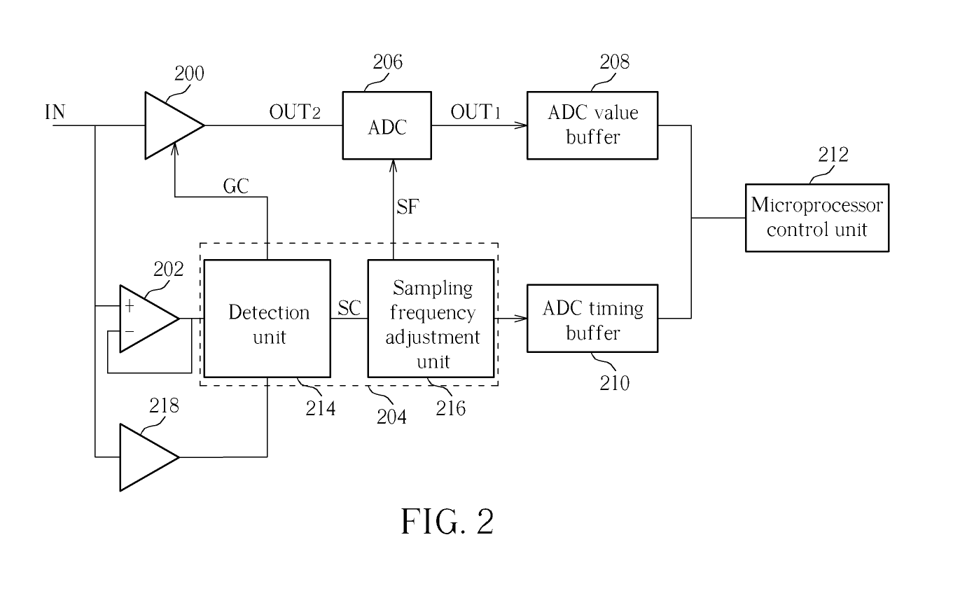

Please refer to FIG. 2, which is a schematic diagram of a battery management system (BMS) 20 according to an embodiment of the present invention. As shown in FIG. 2, the BMS 20 is preferably utilized for managing a battery set providing power for a motor, and includes a programmable gain amplifier 200, an amplifier 202, an adjustment module 204, an analog to digital converter (ADC) 206, an ADC value buffer 208, an ADC timing buffer 210 and a microprocessor control unit 212. In short, the adjustment module 204 includes a detection unit 214 and a sampling frequency adjustment unit 216. The detection unit 214 detects a slop of an input current IN, i.e. variation, to generate a sampling control signal SC, wherein the battery set provides the input current IN for the motor. The sampling frequency adjustment unit 216 adjusts a sampling frequency SF of the ADC 206 according to the sampling control signal SC, such that the ADC 206 can generate an ADC output signal OUT₁ according to the sampling frequency SF. As a result, the BMS 20 can dynamically control the sampling frequency SF of the ADC 206, such that the ADC 206 can have a low power consumption when the motor rotates in a stable state, i.e. low input current, and can accurately measure the input current IN when the motor just starts rotating or suddenly accelerates, i.e. sudden high input current.

In detail, the amplifier 202 can be a differential amplifier in a negative feedback configuration and receives an input signal correlated to the input current IN, such that the detection unit 214 can detect the slop of an input current IN according to an output of the amplifier 202, and thus the sampling frequency adjustment unit 216 can adjust the sampling frequency SF in proportional to the slop of the input current IN, or just switch the sampling frequency SF between a frequency F1 and a frequency F2 according to the slop of the input current IN, e.g. adjusting the sampling frequency SF from the frequency F1 to the frequency F2 when the slop of the input current IN is higher than a slop threshold, wherein the frequency F1 is higher than the frequency F2. As a result, the BMS 20 can have a low sampling frequency SF of the ADC 206 and thus have a low power consumption when the motor rotates in a stable state, while having a high sampling frequency SF of the ADC 206 and thus accurately measuring the input current IN when the motor just starts rotating or suddenly accelerates.

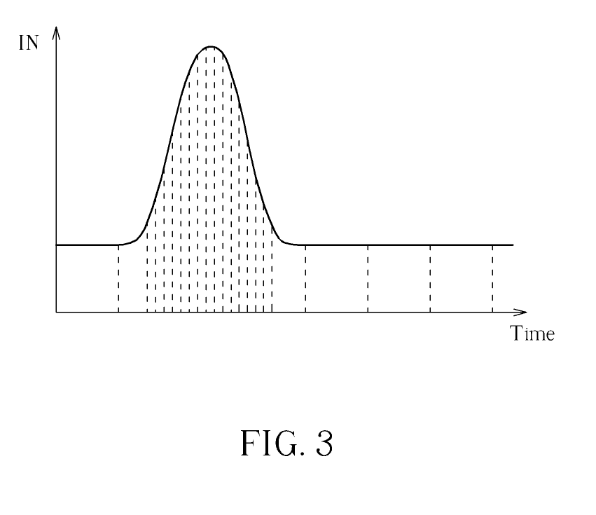

For example, please refer to FIG. 3, which is a schematic diagram of the BMS 20 shown in FIG. 2 sampling the input current IN according to an embodiment of the present invention, wherein dotted lines indicate sampling timings. As shown in FIG. 3, when the input current IN suddenly increases, the sampling frequency SF of the ADC 206 increases as well, so as to accurately measure the input current

IN.

Besides, please continue refer to FIG. 2. The BMS 20 can further include an amplifier 218 for receiving the input signal correlated to the input current IN, such that the detection unit 214 can detect a magnitude of an input current IN according to an output of the amplifier 202, to generate a gain control signal GC for the programmable gain amplifier 200. Then, the programmable gain amplifier 200 adjusts a variable gain according to the gain control signal GC, to amplify the received input signal correlated to the input current IN, so as to generate an output signal OUT₂ for the ADC 206. Under such a situation, the variable gain of the programmable gain amplifier 200 decreases when the magnitude of the input current IN is higher than a magnitude threshold. As a result, the BMS 20 can prevent the ADC 206 from being saturated by the output signal OUT₂ when the motor just starts rotating or suddenly accelerates.

Moreover, the ADC value buffer 208 can store an ADC value of the ADC output signal OUT₁ of the ADC 208, and the ADC timing buffer 210 can store an ADC timing of the ADC output signal OUT₁ of the ADC 208, such that the microprocessor control unit 212 can derive the input current IN according the ADC value, the variable gain of the programmable gain amplifier 200 and the ADC timing. As a result, the BMS 20 can accurately measure capacity of the battery set for battery management.

Noticeably, the above embodiment is to detect the slop and the magnitude of the input current IN, so as to adjust the sampling frequency SF and an input power of the ADC 206, and thus accurately measure the input current IN and prevent the ADC 206 from saturation due to the sudden large input current IN when the motor just starts rotating or suddenly accelerates. Those skilled in the art should make modifications or alterations accordingly. For example, the adjustment module 204 is not limited to be applied for the ADC 206 of the BMS 20 for managing the battery set providing power for the motor, and can be utilized for an ADC measuring any signal with a sudden increase. Besides, elements for measuring the slop and the magnitude of the input current IN is not limited to the amplifier 202, 218, and can be other elements.

In the prior art, the conventional ADC is over-designed to have a wide dynamic range and a high large sampling frequency, to avoid saturation and inaccuracy due to the sudden large current of the motor, causing more power consumption and design complexity. In comparison, the present invention detects the slop and the magnitude of the input current IN, so as to adjust the sampling frequency SF and an input power of the ADC 206, and thus accurately measure the input current IN and prevent the ADC 206 from saturation due to the sudden large input current IN when the motor just starts rotating or suddenly accelerates.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adjustment module for an analog to digital converter (ADC) of a battery management system (BMS), the adjustment module comprising:
a detection unit, for detecting a slop of an input current, to generate a sampling control signal; and
a sampling frequency adjustment unit, for adjusting a sampling frequency of the ADC according to the sampling control signal.

2. The adjustment module of claim 1, wherein the sampling frequency adjustment unit adjusts the sampling frequency in proportional to the slop of the input current.

3. The adjustment module of claim 1, wherein the sampling frequency adjustment unit adjusts the sampling frequency from a first frequency to a second frequency when the slop of the input current is higher than a slop threshold, and the first frequency is higher than the second frequency.

4. The adjustment module of claim 1, wherein the detection unit detects a magnitude of the input current, to generate a gain control signal.

5. The adjustment module of claim 4, wherein the BMS comprises a programmable gain amplifier, for adjusting a variable gain according to the gain control signal, to generate an output signal for the ADC.

6. The adjustment module of claim 5, wherein the variable gain of the programmable gain amplifier decreases when the magnitude of the input current is higher than a magnitude threshold.

7. The adjustment module of claim 1, wherein the BMS comprises:
an ADC value buffer, for storing an ADC value of an ADC output signal of the ADC; and
an ADC timing buffer, for storing an ADC timing of the ADC output signal of the ADC.

8. A battery management system (BMS), comprising:
an analog to digital converter (ADC), for generating an ADC output signal according to a sampling frequency; and
an adjustment module, comprising:
a detection unit, for detecting a slop of an input current, to generate a sampling control signal; and
a sampling frequency adjustment unit, for adjusting the sampling frequency of the ADC according to the sampling control signal.

9. The BMS of claim 8, wherein the sampling frequency adjustment unit adjusts the sampling frequency in proportional to the slop of the input current.

10. The BMS of claim 8, wherein the sampling frequency adjustment unit adjusts the sampling frequency from a first frequency to a second frequency when the slop of the input current is higher than a slop threshold, and the first frequency is higher than the second frequency.

11. The BMS of claim 8, wherein the detection unit detects a magnitude of the input current, to generate a gain control signal.

12. The BMS of claim 11, further comprising a programmable gain amplifier, for adjusting a variable gain according to the gain control signal, to generate an output signal for the ADC.

13. The BMS of claim 12, wherein the variable gain of the programmable gain amplifier decreases when the magnitude of the input current is higher than a magnitude threshold.

14. The BMS of claim 8 further comprising:
an ADC value buffer, for storing an ADC value of an ADC output signal of the ADC; and
an ADC timing buffer, for storing an ADC timing of the ADC output signal of the ADC.
